(19) United States
(12) Patent Application Publication
(10) Pub. No.: US 2011/0304992 A1
(43) Pub. Date: Dec. 15, 2011

(54) HEAT DISSIPATION DEVICE

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/836,541

(22) Filed: Jul. 14, 2010

(30) Foreign Application Priority Data
Jun. 15, 2010 (TW) 99119594

(51) Int. Cl. H05K 7/20

(52) U.S. Cl. 361/720

(57) ABSTRACT

A heat dissipation device is used to cool a storage device. The heat dissipation device includes a heat sink and two parallel conduction boards. The heat sink includes a base and a number of fins extending from a first side of the base. A guiding channel is defined between every two adjacent fins to guide airflow. The two conduction boards are attached to a second side of base opposite to the first side. A receiving space is defined between the two conduction boards for receiving the storage device therein.

### BACKGROUND

1. Technical Field

The present disclosure relates to heat dissipation devices and, particularly, to a heat dissipation device for a storage device.

2. Description of Related Art

Electronic devices (such as storage devices) may produce a large amount of heat. With the development of technology, the speed of the storage device becomes faster and faster. More heat accordingly generated by the electronic device must be quickly dissipated to protect the electronic device from damage. It is not enough to apply a typical system fan to cool the storage device.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an exemplary embodiment of a heat dissipation device which is applied to cool a storage device.

FIG. 2 is an assembled view of FIG. 1.

FIG. 3 is a schematic view of a plurality of heat dissipation devices applied to cool a plurality of storage devices.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

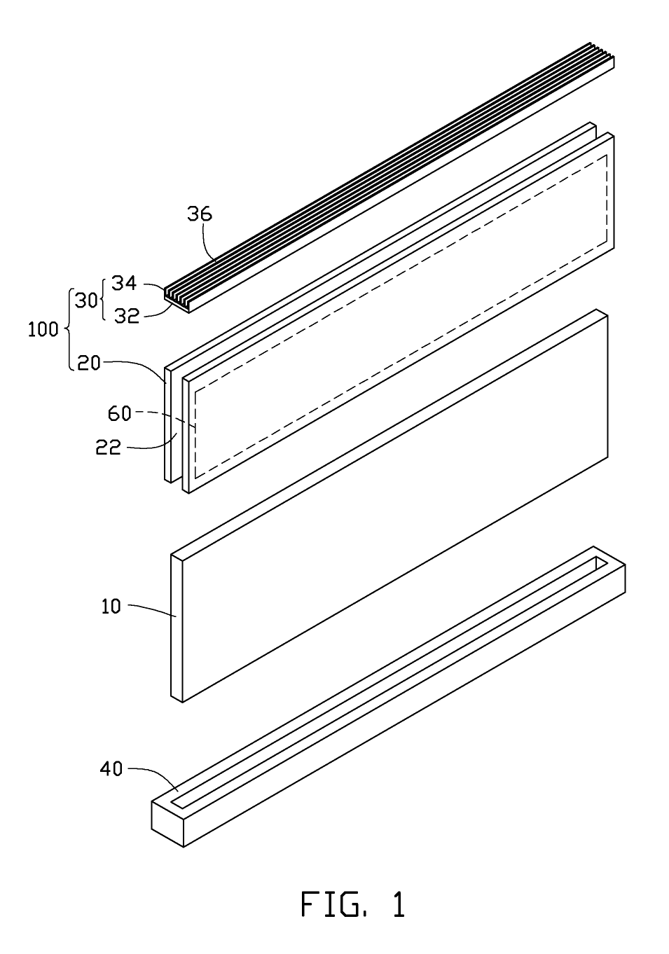

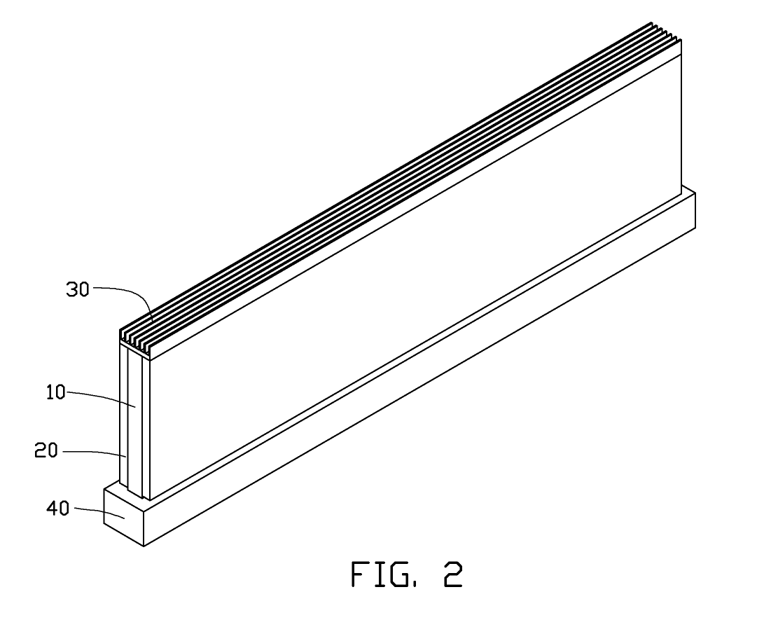

Referring to FIGS. 1 and 2, an exemplary embodiment of a heat dissipation device 100 is used to cool a storage device, such as a memory 10 which is inserted into a storage slot 40 of a circuit board. In the embodiment, the storage slot 40 is a memory slot and the circuit board is a motherboard. The heat dissipation device 100 includes two parallel conduction boards 20, and a heat sink 30. Each conduction board 20 is rectangular. A conduction medium 60 is attached to a side of each conduction board 20 to conduct heat. The heat sink 30 includes a rectangular base 32, and a plurality of fins 34 perpendicularly extending from the top of the base 32. A guiding channel 36 is defined between every two adjacent fins 34 to guide airflow. The two conduction boards 20 are perpendicularly attached to the bottom of the base 32 of the heat sink 30, with the tops of the conduction boards 20 affixed to the bottom of the base 32 by using thermal glue or soldering. A receiving space 22 is defined between the two conduction boards 20 to receive any of the exposed portion of the memory 10 extending from the memory slot 40, with the conduction mediums 60 contacting two sides of the memory 10.

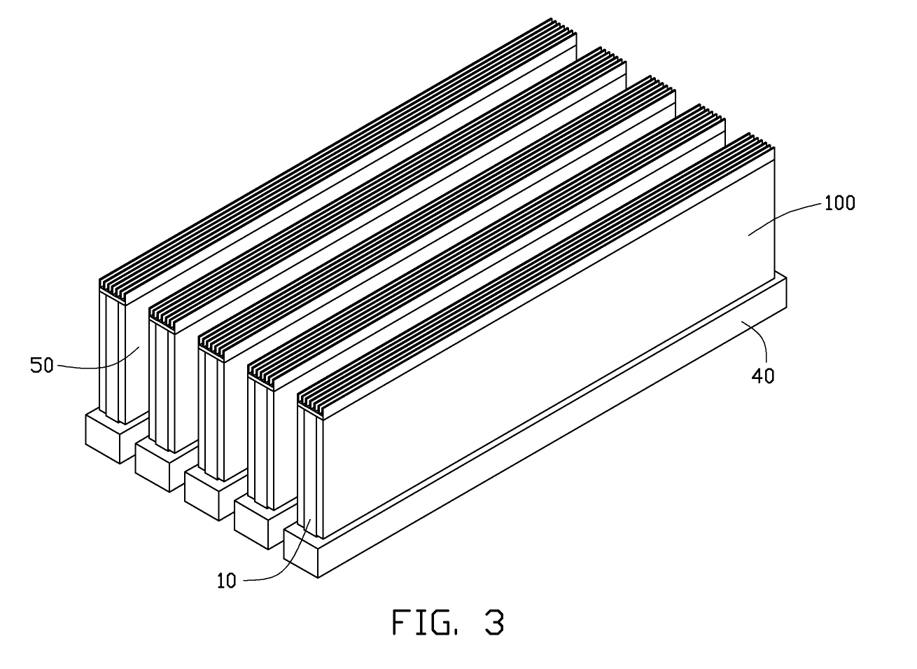

Referring to FIG. 3, when a plurality of memories 10 is inserted into a plurality of memory slots 40, each memory 10 is enclosed in its own heat dissipation device 100, and a passage 50 is defined between every two adjacent heat dissipation devices 100 to guide air to pass therethrough to dissipate heat generated by the memories 10. In the embodiment, a height of each fin 34 is substantially equal to 2 millimeters, to avoid interfering with other elements. The material of the two conduction boards 20 are aluminum. In other embodiments, the height of the fins 34 and the material of the two conduction boards 20 can be adjusted according to need.

In use, the heat dissipation device 100 encloses any of the exposed portion of the memory 10 extending from the memory slot 40. Heat generated by the memory 10 is conducted to the conduction boards 20 by the conduction mediums 60. The guiding channel 36 and the passage 50 may guide air passing through the fins 34 of the heat sink 30 and any other heat dissipation devices 100.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A heat dissipation device for cooling a storage device, the heat dissipation device comprising:
a heat sink comprising a base, and a plurality of fins extending from a first side of the base, a guiding channel being defined between every two adjacent fins to guide air; and
two parallel conduction boards attached to a second side of the base opposite to the first side, a receiving space being defined between the two conduction boards for receiving the storage device therein.

2. The heat dissipation device of claim 1, wherein conduction mediums are respectively attached to sides of the conduction boards, and the conduction mediums face toward each other and are configured to conduct heat from the storage device to the conduction boards.

3. The heat dissipation device of claim 1, wherein the two conduction boards are attached to the base of the heat sink by using thermal glue or soldering.

4. A heat dissipation assembly, comprising:
a plurality of storage devices operable to insert into a plurality of storage slots of a circuit board;
a plurality of heat dissipation devices, each of the heat dissipation devices receiving a respective one of the storage devices, a passage being defined between every two adjacent dissipation devices to guide air, each heat dissipation device comprising:
a heat sink comprising a base, and a plurality of fins extending from the base, a guiding channel being defined between every two adjacent fins to guide air; and
two parallel conduction boards attached to the base opposite to the fins, a receiving space being defined between the conduction boards to receive one of the storage devices therein with the conduction boards contacting the storage device.

5. The heat dissipation assembly of claim 4, wherein a conduction medium is positioned on a side of each of the conduction boards, and the conduction mediums of the two conduction boards of each heat dissipation device face to each other.

6. The heat dissipation assembly of claim 5, wherein the two conduction boards are mounted to the base of the heat sink by using thermal glue or soldering.
